(19) United States
(12) Patent Application Publication
(10) Pub. No.: US 2017/0330777 A1
(43) Pub. Date: Nov. 16, 2017

(54) PLASMA-PROCESSING DETECTION INDICATOR IN WHICH METAL OXIDE FINE PARTICLES ARE USED AS COLOR-CHANGE LAYER

(71) Applicant: SAKURA COLOR PRODUCTS CORPORATION, Osaka-shi, Osaka (JP)

(72) Inventors: Keita Hishikawa, Osaka-shi (JP); Kazuhiro Uneyama, Osaka-shi (JP)

(73) Assignee: SAKURA COLOR PRODUCTS CORPORATION, Osaka-shi, Osaka (JP)

(21) Appl. No.: 15/529,404

(22) PCT Filed: Nov. 24, 2015
(86) PCT No.: PCT/JP2015/082818

§ 371 Date: May 24, 2017

(30) Foreign Application Priority Data
Dec. 2, 2014 (JP) 2014-244416

(51) Int. Cl. H01L 21/67; H01J 37/244; G01N 21/78

(52) U.S. Cl. CPC H01L 21/67253; G01N 21/78; H01J 37/244

(57) ABSTRACT

The present invention provides a plasma treatment detection indicator including a color-changing layer that changes color by plasma treatment, exhibiting excellent heat resistance, with the gasification of the color-changing layer or the scattering of the fine debris of the color-changing layer caused by the plasma treatment being suppressed to the extent that electronic device properties are not affected. Specifically, the present invention provides a plasma treatment detection indicator comprising a color-changing layer that changes color by plasma treatment, the color-changing layer comprising metal oxide fine particles containing at least one element selected from the group consisting of Mo, W, Sn, V, Ce, Te, and Bi, the metal oxide fine particles having a mean particle size of 50 μm or less.

### TECHNICAL FIELD

The present invention relates to a plasma treatment detection indicator in which metal oxide fine particles are used as a color-changing layer, the indicator being useful as an indicator particularly for use in an electronic device production equipment.

### BACKGROUND ART

In the production process of electronic devices, a variety of treatments have been performed on the electronic device substrate (substrate to be treated). In the case of, for example, a semiconductor as the electronic device, a semiconductor wafer (wafer) is loaded; after that, a film-forming step of forming an insulating film or a metal film, a photolithography step of forming a photoresist pattern, an etching step of processing the film using the photoresist pattern, an impurity-adding step of forming a conductive layer on the semiconductor wafer (also called doping or diffusion process), a CMP step of polishing the uneven surface of the film to flatten the surface (chemical mechanical planarization), and the like are performed, followed by semiconductor wafer electrical characteristics inspection for inspecting the finish of the pattern or the electrical characteristics (these steps may be collectively referred to as the front-end process). Subsequently, the back-end process of forming semiconductor chips follows. This front-end process is also performed not only when the electronic device is a semiconductor, but also when other electronic devices (e.g., light-emitting diodes (LED), solar batteries, liquid crystal displays, and organic EL (Electro-Luminescence) displays) are produced.

The front-end process includes, in addition to the steps described above, a washing step using plasma, ozone, ultraviolet rays, and the like, and a step of removing a photoresist pattern using plasma, radical-containing gas, and the like (also called ashing or ash removal). The film-forming step also includes CVD for forming a film by chemically reacting a reactive gas on the wafer surface, and sputtering for forming a metal film. The etching step includes, for example, dry etching performed by chemical reaction in plasma, and etching by ion beams. The “plasma” refers to the state in which gas is dissociated, and ions, radicals, and electrons are present in the plasma.

In the production process of electronic devices, the various treatments described above must be properly performed to secure the performance, reliability, and the like of electronic devices. Thus, in the plasma treatment represented by a film-forming step, an etching step, an ashing step, an impurity-adding step, a washing step, etc., a completion check and the like is performed to confirm the completion of the plasma treatment, for example, by emission analysis of plasma with a spectrometer, or by using a plasma treatment detection indicator comprising a color-changing layer that changes color in a plasma treatment atmosphere.

As an example of the plasma treatment detection indicator, Patent Literature 1 discloses an ink composition for detecting a plasma treatment comprising 1) at least one of anthraquinone colorants, azo colorants, or phthalocyanine colorants; and 2) at least one of binder resins, cationic surfactants, or extenders, wherein a plasma-generating gas used in the plasma treatment contains at least one of oxygen or nitrogen. Patent Literature 1 also discloses a plasma treatment detection indicator comprising a color-changing layer that comprises the ink composition formed on a base material.

Patent Literature 2 discloses an ink composition for detecting inert gas plasma treatment, comprising (1) at least one of anthraquinone colorants, azo colorants, and methine colorants; and (2) at least one of binder resins, cationic surfactants and extenders, the inert gas containing at least one selected from the group consisting of helium, neon, argon, krypton, and xenon. Patent Literature 2 also discloses a plasma treatment detection indicator in which a color-changing layer comprising the ink composition is formed on a base material.

However, the check method using emission analysis or a traditional plasma treatment detection indicator may be insufficient in performance as an indicator for use in an electronic device production equipment. Specifically, because of the limitation to the measurement and analysis performed through the window provided to the electronic device production equipment, it tends to be difficult to perform efficient measurement or analysis with the check method using emission analysis when the inside of the electronic device production equipment cannot be thoroughly seen. Although the use of a traditional plasma treatment detection indicator is a convenient and excellent means for confirming the completion of plasma treatment through the color change of the color-changing layer, the organic components contained in the color-changing layer, such as a colorant, a binder resin, and a surfactant, may possibly lead to decreased cleanliness of the electronic device production equipment, or contamination of electronic devices due to gasification of the organic components or scattering of the fine debris of the organic components caused by plasma treatment. The gasification of organic components may adversely affect the vacuum performance of the electronic device production equipment. In addition, because of the insufficient heat resistance of the traditional color-changing layer composed primarily of organic components, it is difficult to use it as an indicator when the electronic device production equipment has a high temperature.

Therefore, there has been a demand for the development of a plasma treatment detection indicator comprising a color-changing layer that changes color by plasma treatment, exhibiting excellent heat resistance with the gasification of the color-changing layer or the scattering of the fine debris of the color-changing layer caused by plasma treatment being suppressed to the extent that electronic device properties are not affected.

### CITATION LIST

### Patent Literature

Patent Literature 1: JP2013-98196A

Patent Literature 2: JP2013-95764A

### SUMMARY OF INVENTION

### Technical Problem

An object of the present invention is to provide a plasma treatment detection indicator comprising a color-changing layer that changes color by plasma treatment, exhibiting excellent heat resistance, with the gasification of the color-changing layer or the scattering of the fine debris of the color-changing layer caused by the plasma treatment being suppressed to the extent that electronic device properties are not affected.

### Solution to Problem

The present inventors conducted extensive research to achieve the object, and found that the use of metal oxide fine particles as a color-changing material contained in a color-changing layer can achieve the object. The inventors have thus completed the present invention.

Specifically, the present invention relates to the following plasma treatment detection indicator.

Item 1. A plasma treatment detection indicator comprising a color-changing layer that changes color by plasma treatment, the color-changing layer comprising metal oxide fine particles containing at least one element selected from the group consisting of Mo, W, Sn, V, Ce, Te, and Bi, the metal oxide fine particles having a mean particle size of 50 μm or less.
Item 2. The plasma treatment detection indicator according to Item 1, wherein the metal oxide fine particles are at least one member selected from the group consisting of molybdenum(IV) oxide fine particles, molybdenum(VI) oxide fine particles, tungsten(VI) oxide fine particles, tin(IV) oxide fine particles, vanadium(II) oxide fine particles, vanadium(III) oxide fine particles, vanadium(IV) oxide fine particles, vanadium(V) oxide fine particles, cerium(IV) oxide fine particles, tellurium (IV) oxide fine particles, bismuth(III) oxide fine particles, bismuth(III) carbonate oxide fine particles, and vanadium(IV) oxide sulfate fine particles.
Item 3. The plasma treatment detection indicator according to Item 1 or 2, wherein the metal oxide fine particles are at least one member selected from the group consisting of molybdenum(VI) oxide fine particles, tungsten(VI) oxide fine particles, vanadium(III) oxide fine particles, vanadium(V) oxide fine particles, and bismuth(III) oxide fine particles.
Item 4. The plasma treatment detection indicator according to any one of items 1 to 3, comprising a base material that supports the color-changing layer.
Item 5. The plasma treatment detection indicator according to any one of items 1 to 4, for use in an electronic device production equipment.
Item 6. The plasma treatment detection indicator according to Item 5, which has a shape that is identical to the shape of an electronic device substrate for use in the electronic device production equipment.
Item 7. The plasma treatment detection indicator according to Item 5 or 6, wherein the electronic device production equipment performs at least one plasma treatment selected from the group consisting of a film-forming step, an etching step, an ashing step, an impurity-adding step, and a washing step.
Item 8. The plasma treatment detection indicator according to any one of Items 1 to 7, comprising a non-color-changing layer that does not change color by plasma treatment.
Item 9. The plasma treatment detection indicator according to Item 8, wherein the non-color-changing layer contains at least one member selected from the group consisting of titanium(IV) oxide, zirconium(IV) oxide, yttrium(III) oxide, barium sulfate, magnesium oxide, silicon dioxide, alumina, aluminum, silver, yttrium, zirconium, titanium, and platinum.
Item 10. The plasma treatment detection indicator according to Item 8 or 9, wherein the non-color-changing layer and the color-changing layer are formed on the base material in sequence, the non-color-changing layer is formed adjacent to the principal surface of the base material, and the color-changing layer is formed adjacent to the principal surface of the non-color-changing layer.

### Advantageous Effects of Invention

In the plasma treatment detection indicator of the present invention, specific metal oxide fine particles are used as a color-changing material contained in the color-changing layer. The color of the color-changing layer is chemically changed because the valence of the metal oxide fine particles is changed by plasma treatment. This suppresses the gasification of the color-changing layer or scattering of the fine debris of the color-changing layer caused by plasma treatment to the extent that electronic device properties are not affected. In addition, because the color-changing material is composed of metal oxide fine particles, the indicator exhibits heat resistance capable of resisting the process temperature applied in electronic device production. The indicator of the present invention is particularly useful as a plasma treatment detection indicator for use in an electronic device production equipment, which must be treated in a vacuum and high-temperature condition, as well as in a highly clean environment. Examples of electronic devices include semiconductors, light-emitting diodes (LED), laser diodes, power devices, solar batteries, liquid crystal displays, and organic EL displays.

### BRIEF DESCRIPTION OF DRAWINGS

FIG. 1 is a schematic cross-sectional view of the ICP-type (ICP: inductively coupled plasma) plasma etching apparatus used in Test Example 1.

FIG. 2 is a graph showing the results of Test Example 1 (the relationship between the mean particle size and ΔE).

FIG. 3 is a schematic cross-sectional view of the CCP-type (parallel plate-type: Capacitively Coupled Plasma-type) plasma etching apparatus used in Test Example 2.

FIG. 4 is a graph showing the results of Test Example 2 (the relationship between the mean particle size and ΔE).

### DESCRIPTION OF EMBODIMENTS

The following describes in detail the plasma treatment detection indicator according to the present invention.

The plasma treatment detection indicator of the present invention (hereinafter sometimes also referred to as “the indicator of the present invention”) comprises a color-changing layer that changes color by plasma treatment. The color-changing layer comprises metal oxide fine particles containing at least one element selected from the group consisting of Mo, W, Sn, V, Ce, Te, and Bi, the metal oxide fine particles having a mean particle size of 50 μm or less (hereinafter sometimes simply referred to as “the metal oxide fine particles”).

In the plasma treatment detection indicator with this feature of the present invention, specific metal oxide fine particles are used as a color-changing material contained in the color-changing layer. The color of the color-changing layer is chemically changed because the valence of the metal oxide fine particles is changed by plasma treatment. This suppresses the gasification of the color-changing layer or the scattering of the fine debris of the color-changing layer caused by plasma treatment to the extent that electronic device properties are not affected. In addition, because the color-changing material is composed of metal oxide fine particles, the indicator exhibits heat resistance capable of resisting the process temperature applied in electronic device production. The indicator of the present invention is particularly useful as a plasma treatment detection indicator for use in electronic device production equipment, which must be treated in a vacuum and high-temperature condition, as well as in a highly clean environment. Examples of electronic devices include semiconductors, light-emitting diodes (LED), laser diodes, power devices, solar batteries, liquid crystal displays, and organic EL displays.

### Color-Changing Layer

The indicator of the present invention comprises a color-changing layer that changes color by plasma treatment, and the color-changing layer comprises metal oxide fine particles containing at least one element selected from the group consisting of Mo, W, Sn, V, Ce, Te, and Bi, the metal oxide fine particles having a mean particle size of 50 μm or less. In particular, in the present invention, plasma treatment causes the valence of the metal oxide fine particles to change, thus chemically changing the color. Unlike organic components, the gasification or the scattering of the fine debris of the metal oxide fine particles caused by plasma treatment is suppressed to the extent that electronic device properties are not affected. In addition, the metal oxide fine particles exhibit heat resistance capable of resisting the process temperature applied in electronic device production.

The metal oxide fine particles are at least one member selected from the group consisting of molybdenum(IV) oxide fine particles, molybdenum(VI) oxide fine particles, tungsten(VI) oxide fine particles, tin(IV) oxide fine particles, vanadium(II) oxide fine particles, vanadium(III) oxide fine particles, vanadium(IV) oxide fine particles, vanadium(V) oxide fine particles, cerium(IV) oxide fine particles, tellurium (IV) oxide fine particles, bismuth(III) oxide fine particles, bismuth(III) carbonate oxide fine particles, and vanadium(IV) oxide sulfate particles. It is possible that the metal oxide fine particles contain a slight amount of crystalline water in the molecules, but it is preferable that the metal oxide fine particles contain no crystalline water to thus exclude the possibility of releasing water molecules (moisture gas).

Of the above, in consideration of the color change by plasma treatment, the metal oxide fine particles are preferably at least one member selected from the group consisting of molybdenum(VI) oxide fine particles, tungsten(VI) oxide fine particles, vanadium(III) oxide fine particles, vanadium(V) oxide fine particles, and bismuth(III) oxide fine particles.

In the indicator of the present invention, the metal oxide fine particles have a mean particle size of 50 μm or less. In particular, it is more preferable that the mean particle size be about 0.01 to 10 μm. The mean particle size as used herein is a value measured with a laser diffraction/scattering particle size distribution measurement device (product name: Microtrac MT3000, produced by Nikkiso Co. Ltd.). The mean particle size of 50 μm or less enables excellent color change (sensitivity) by plasma treatment.

In the indicator of the present invention, the color-changing layer comprises the metal oxide fine particles mentioned above. It is desired that the color-changing layer be substantially formed from metal oxide fine particles, and it is preferable that organic components and the like other than the metal oxide fine particles be excluded. The metal oxide fine particles are contained in the form of aggregates (dry matter) or the like.

The method for forming a color-changing layer is not limited. The color-changing layer may be formed, for example, by preparing a slurry containing metal oxide fine particles having a mean particle size of 50 μm or less, applying the slurry onto a substrate, and evaporating the solvent, followed by drying in the atmosphere.

The metal oxide fine particles having a mean particle size of 50 μm or less may also be prepared by calcining the starting material powder of metal oxide fine particles to obtain an oxide, and then suitably adjusting the mean particle size. To adjust the mean particle size of metal oxide fine particles to be less than 50 μm, for example, a shearing device, such as a known bead mill or a three-roll mill, may be used to adjust the particle size to a predetermined range.

The starting material powder refers to a powder that is converted into a metal oxide by calcination, such as hydroxides, carbonates, acetylacetonato complexes, oxide salts, oxoacids, oxoacid salts, and oxo complexes, each containing the metal element (at least one member of Mo, W, Sn, V, Ce, Te, and Bi). The oxoacids include not only ortho acids and meta acids, but also condensed oxoacids, such as isopoly acids and heteropoly acids.

Specific examples of the starting material powder for the metal oxide fine particles include vanadium(III) acetylacetonate, bismuth(III) nitrate, bismuth(III) hydroxide, bismuth(III) hydroxide nitrate, bismuth(III) carbonate oxide, bismuth(III) acetate oxide, bismuth(III) sulfate, bismuth(III) chloride, hexaammonium heptamolybdate tetrahydrate, ammonium tungstate para pentahydrate, ammonium vanadate(V), molybdenum dioxide acetonato, tungstic acid, molybdic acid, isopolytungstic acid, isopolymolybdic acid, isopolyvanadium acid, and the like. These starting material powders are converted into metal oxide by calcination; however, depending on the calcination conditions, there may be a case in which they are not completely converted into metal oxide. Thus, it is acceptable if, depending on the calcination conditions, a slight amount of an unreacted component or organic component remains in the metal oxide fine particles to the degree that the remains do not affect the effect of the present invention.

As a method for forming a coating film by applying a slurry to a substrate, for example, a wide range of known coating methods, such as spin coating, slit coating, spray coating, and dip coating, and a wide range of known printing methods, such as silk-screen printing, gravure printing, offset printing, relief printing, and flexographic printing, may be used.

A substrate on which a coating film of a slurry containing the metal oxide fine particles is formed may also be used as a substrate (base material for supporting the color-changing layer) of the indicator of the present invention described later.

The thickness of the color-changing layer of the indicator of the present invention is not limited, and is preferably about 500 nm to 2 mm, and more preferably about 1 to 100 μm.

Base Material that Supports Color-Changing Layer

The indicator of the present invention may comprise a base material that supports the color-changing layer.

The base material is not particularly limited as long as the color-changing layer is formed thereon and as long as the base material can support the color-changing layer. Examples of usable base materials include metals or alloys, ceramic, quartz, glass, silicon wafers, concrete, plastics (e.g., polyethylene terephthalate (PET), polytetrafluoroethylene (PTFE), polyether ether ketone (PEEK), polypropylene, nylon, polystyrene, polysulfone, polycarbonate, and polyimide), fabrics (non-woven fabrics, woven fabrics, glass fiber filters, and other fiber sheets), and composite materials thereof. Those typically known as an electronic device substrate, such as silicon, gallium arsenide, silicon carbide, sapphire, glass, gallium nitride, and germanium, can also be used as a base material of the indicator of the present invention. The thickness of the base material can suitably be determined in accordance with the type of the indicator.

### Non-Color-Changing Layer

To enhance the visibility of the color-changing layer, the indicator of the present invention may be provided with, as an underlayer, a non-color-changing layer that does not change color by plasma treatment. The non-color-changing layer is required to not be gasified, as well as being heat resistant. The non-color-changing layer is preferably a white layer, a metal layer, and the like.

The white layer may be formed using, for example, titanium(IV) oxide, zirconium(IV) oxide, yttrium(III) oxide, barium sulfate, magnesium oxide, silicon dioxide, or alumina.

The metal layer may be formed using, for example, aluminum, silver, yttrium, zirconium, titanium, or platinum.

Examples of the method for forming a non-color-changing layer include physical vapor deposition (PVD), chemical vapor deposition (CVD), and sputtering. The layer may also be formed by preparing a slurry containing a substance that forms a non-color-changing layer, applying the slurry onto a substrate, evaporating the solvent, and calcining the substrate in the atmosphere. Examples of slurry application and printing methods include a wide range of known coating methods and printing methods, such as spin coating, slit coating, spray coating, dip coating, silk-screen printing, gravure printing, offset printing, relief printing, and flexographic printing. The thickness of the non-color-changing layer can suitably be determined in accordance with the type of indicator.

In the present invention, any combination of the color-changing layer and the non-color-changing layer is possible, as long as the completion of the plasma treatment is confirmed. For example, the color-changing layer and the non-color-changing layer may be formed such that the color difference between the color-changing layer and the non-color-changing layer is identified after the color-changing layer undergoes a color change, or such that the color difference between the color-changing layer and the non-color-changing layer is eliminated after color change. In the present invention, it is preferable to form a color-changing layer and a non-color-changing layer particularly such that the color difference between the color-changing layer and the non-color-changing layer is identified after the color-changing layer undergoes a color change.

To enable the identification of color difference, a color-changing layer and a non-color-changing layer may be formed, for example, such that at least one of characters, patterns, and symbols appears because of the change in color of the color-changing layer. In the present invention, characters, patterns, and symbols include any information that signals a change in color. These characters, etc., may be suitably designed in accordance with the intended use or other purposes.

The color-changing layer and the non-color-changing layer before color change may have different colors. Both of the color-changing layer and the non-color-changing layer may have, for example, substantially the same color, and color difference (contrast) between the layers may be identified for the first time after color change.

In the present invention, examples of preferable embodiments of the layered structure include (i) an indicator in which the color-changing layer is formed adjacent to at least one principal surface of a base material; and (ii) an indicator in which the non-color-changing layer and the color-changing layer are formed in sequence on a base material, with the non-color-changing layer formed adjacent to the principal surface of the base material and the color-changing layer formed adjacent to the principal surface of the non-color-changing layer.

### Adhesion Layer

The indicator of the present invention may optionally comprise an adhesion layer on a back surface (a surface that is in contact with a bottom of the plasma treatment device where the indicator is disposed at the bottom). It is preferable that an adhesion layer be formed on the back surface of the indicator, because the indicator of the present invention is thereby securely fixed to a desired portion in the plasma treatment device (e.g., an object to be subjected to plasma treatment, the bottom of the device etc.).

The components of the adhesion layer are preferably those whose gasification by plasma treatment is suppressed. As such components, for example, special adhesives are preferable, and of these, silicone-based adhesives are preferable.

### Shape of the Indicator of the Present Invention

The shape of the indicator of the present invention is not particularly limited, and a wide range of shapes adopted for known plasma treatment detection indicators can be used. When the indicator of the present invention has a shape that is identical to the shape of an electronic device substrate for use in an electronic device production equipment, it becomes possible to easily detect whether plasma treatment is homogeneously performed on the entire electronic device substrate using the indicator as a “dummy substrate.”

As used herein, the phrase “the indicator of the present invention has a shape that is identical to the shape of an electronic device substrate for use in an electronic device production equipment” includes both of the following meanings: (i) the shape of the indicator is completely the same as the shape of the electronic device substrate used in the electronic device production equipment; and (ii) the shape of the indicator is substantially the same as the shape of the electronic device substrate used in electronic device production equipment to the degree that the indicator can be placed (set) in the setting position on the electronic device substrate in the electronic device production equipment that performs plasma treatment.

The phrase “substantially the same” in meaning (ii) above includes, for example, the following meaning: the difference in length between the principal surface of the electronic device substrate (when the shape of the principal surface of the substrate is circular, then the diameter; when the shape of the principal surface of the substrate is square, rectangular, or the like, then the length and width) and the principal surface of the indicator of the present invention is within ±5.0 mm; and the difference in thickness between the electronic device substrate and the indicator of the present invention is within about ±1000 μm.

The indicator of the present invention is not limited to the use in an electronic device production equipment. However, when used in an electronic device production equipment, the indicator is preferably used in an electronic device production equipment that performs at least one step selected from the group consisting of a film-forming step, an etching step, an ashing step, an impurity-adding step, and a washing step by plasma treatment.

### Plasma

The plasma is not particularly limited, and plasma generated with a plasma-generating gas may be used. Of plasma, preferable is plasma that is generated with at least one plasma-generating gas selected from the group consisting of oxygen, nitrogen, hydrogen, chlorine, argon, silane, ammonia, sulfur bromide, boron trichloride, hydrogen bromide, water vapor, nitrous oxide, tetraethoxysilane, nitrogen trifluoride, carbon tetrafluoride, perfluoro cyclobutane, difluoromethane, trifluoromethane, carbon tetrachloride, silicon tetrachloride, sulfur hexafluoride, hexafluoroethane, titanium tetrachloride, dichlorosilane, trimethylgallium, trimethylindium, and trimethylaluminum. Of these plasma-generating gasses, particularly preferable is at least one member selected from the group consisting of carbon tetrafluoride, perfluoro cyclobutane, trifluoromethane, sulfur hexafluoride, and a mixed gas of argon and oxygen.

Plasma can be generated with a plasma treatment apparatus (an apparatus for performing plasma treatment by applying alternating-current power, direct-current power, pulse power, high-frequency power, microwave power, or the like in an atmosphere containing a plasma-generating gas to generate plasma). Particularly in an electronic device production equipment, plasma treatment is used in a film-forming step, an etching step, an ashing step, an impurity-adding step, a washing step, and the like described later.

In a film-forming step, for example, a film can be grown on a semiconductor wafer at a low temperature of 400° C. or lower at a relatively high growth rate by using both plasma and thermal energy in plasma CVD (chemical vapor deposition). Specifically, a material gas is introduced into a depressurized reaction chamber, and the gas is radical ionized by plasma excitation to allow a reaction. Plasma CVD include capacitively coupled plasma-type (anodic bonding-type or parallel plate-type), inductively coupled plasma-type, and ECR (electron cyclotron resonance) plasma-type.

Another film-forming step is a step by sputtering. A specific example is that when tens to thousands of voltage is applied between a semiconductor wafer and a target in an inert gas (e.g., Ar) of about 1 Torr to 10⁻⁴ Torr in a high-frequency discharge sputtering apparatus, ionized Ar is accelerated toward the target and collides with the target; this causes the target substance to be sputtered and deposited on the semiconductor wafer. At this stage, high-energy γ⁻ electrons are generated from the target at the same time. When colliding with Ar atoms, the γ⁻ electrons ionize Ar atoms (Ar⁺), thereby maintaining plasma.

Another film-forming step is a step by ion plating. A specific example is that the inside is made a high-vacuum condition of about 10⁻⁵ Torr to 10⁻⁷ Torr, and then an inert gas (e.g., Ar) or a reactive gas (e.g., nitrogen and hydrocarbon) is injected thereinto. Then, from the thermionic cathode (electron gun) of a processing apparatus, an electron beam is discharged toward the deposition material to generate plasma in which ions and electrons are separately present. Subsequently, a metal is heated and vaporized at a high temperature by an electron beam, and the vaporized metal particles are subjected to a positive voltage, allowing the electrons and the metal particles to collide in plasma. This causes the metal particles to become positive ions, which proceed toward the object to be processed; at the same time, the metal particles bind to a reactive gas to promote a chemical reaction. The particles, for which a chemical reaction has been promoted, are accelerated toward the object to be processed to which negative electrons have been added, collide with the object with high energy, and are thereby deposited as a metal compound on the surface. A vapor deposition method similar to ion plating is also an example of a film-forming step.

In addition, the oxidizing and nitriding step includes a method for converting the semiconductor wafer surface into an oxide film by plasma oxidation using, for example, ECR plasma or surface wave plasma; and a method for converting the semiconductor wafer surface into a nitride film by introducing an ammonia gas, and dissociating, decomposing, and ionizing the ammonia gas by plasma excitation.

In the etching step, for example, in a reactivity ion etching apparatus (RIE), circular plate electrodes are placed in parallel, and a reaction gas is introduced into a depressurized reaction chamber (chamber). The introduced reaction gas is then radicalized or ionized by plasma excitation such that the radicals or ions are present between the electrodes. The etching step uses the effects of both etching that causes a substance on the semiconductor wafer to volatize by using a chemical reaction between these radicals or ions and the material; and physical sputtering. As a plasma etching apparatus, a barrel-type (cylindrical) etching apparatus, as well as the parallel plate-type etching apparatus, can be used.

Another etching step is reverse sputtering. Reverse sputtering is similar in principle to sputtering. Reverse sputtering is an etching method in which ionized Ar in plasma is allowed to collide with the semiconductor wafer. Ion beam etching, similar to reverse sputtering, is also an example of the etching step.

In the ashing step, for example, a photoresist is decomposed and volatilized using oxygen plasma obtained by the plasma excitation of oxygen gas under reduced pressure.

In the impurity-adding step, for example, a gas containing impurity atoms for doping is introduced into a depressurized chamber, and plasma is excited to ionize the impurities. A negative bias voltage is applied to the semiconductor wafer to dope the wafer with the impurity ions.

The washing step is a step for removing foreign materials adhered to the semiconductor wafer without causing damage to the wafer before performing each step on the wafer. Examples include plasma washing that causes a chemical reaction with oxygen gas plasma, and plasma washing (reverse sputtering) that physically removes foreign materials by inert gas (e.g., argon) plasma.

### EXAMPLES

The following describes the present invention in detail by showing Examples and Comparative Examples.

In the following Examples and Comparative Examples, the following samples (all of these are bismuth(III) oxides) were used.

Sample 1: Bi₂O₃ fine particles (mean particle size: 0.05 μm)

Sample 2: Bi₂O₃ fine particles (mean particle size: 0.20 μm)

Sample 3: Bi₂O₃ fine particles (mean particle size: 3.20 μm)

Sample 4: Bi₂O₃ fine particles (mean particle size: 7.80 μm)

Sample 5: Bi₂O₃ fine particles (mean particle size: 12.7 μm)

Sample 6: Bi₂O₃ fine particles (mean particle size: 21.2 μm)

Sample 7: Bi₂O₃ fine particles (mean particle size: 51.8 μm; Comparative Example)

A slurry of the formulation shown in Table 1 below was prepared and applied to a polyimide film to print a 20-μm coating film of Bi₂O₃ fine particles on the polyimide film. This prepared an indicator having a thin color-changing layer deposited on the polyimide film.

TABLE 1

| Name of Substance | wt % |
|---|---|
| Bismuth(III) oxide | 30 |
| Inorganic extender | 3 |
| Butyral resin | 7 |
| Butyl cellosolve | 60 |
| Total | 100 |

### Test Example 1

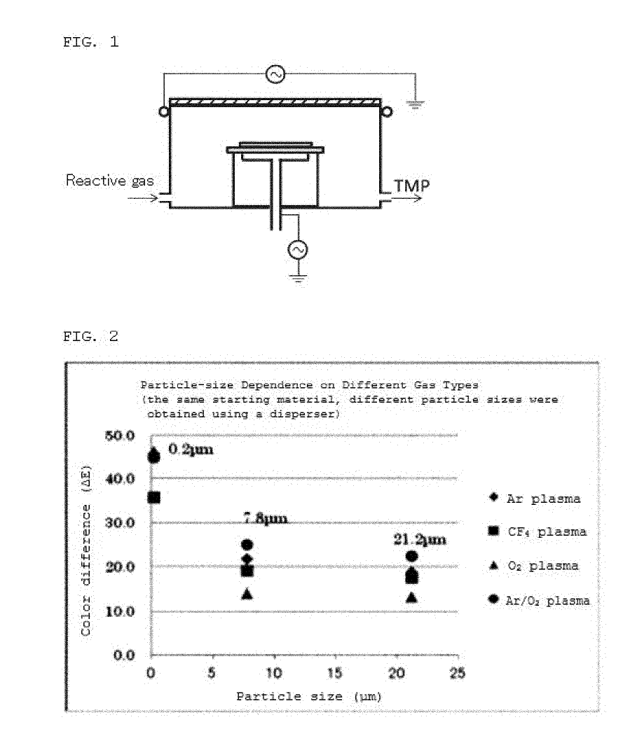

FIG. 1 is a schematic cross-sectional view of an ICP-type (ICP: inductively coupled plasma) plasma etching apparatus.

The apparatus is provided with a chamber capable of evacuating the inside and a stage on which a wafer, which is an object to be treated, is placed. The chamber is provided with a gas inlet from which a reactive gas is introduced, and an exhaust outlet for evacuating the chamber. The stage is provided with an electrostatic adsorption power source for electrostatically adsorbing a wafer, and a cooling mechanism through which a cooling medium for cooling circulates. A coil for plasma excitation and a high-frequency power source as an upper electrode are provided above the chamber.

When etching is actually performed, a wafer is delivered from a wafer inlet into the chamber, and electrostatically adsorbed onto the stage by the electrostatic adsorption power source. Subsequently, a reactive gas is introduced into the chamber. The chamber is depressurized and evacuated with a vacuum pump, and adjusted to a predetermined pressure. Subsequently, high-frequency power is applied to the upper electrode to excite the reactive gas, thereby generating plasma in the space above the wafer. Alternatively, bias may be applied by the high-frequency power source connected to the stage. When the latter is the case, ions in plasma enter the wafer in an accelerated manner. The action of the generated plasma excited species etches the surface of the wafer. During the plasma treatment, helium gas flows through the cooling mechanism provided to the stage, thus cooling the wafer.

In Test Example 1, the indicators prepared using sample 2 (mean particle size: 0.20 μm), sample 4 (mean particle size: 7.80 μm), and sample 6 (mean particle size: 21.2 μm) were individually placed in this apparatus, and argon (Ar), carbon tetrafluoride gas (CF₄), oxygen (O₂), and a mixed gas of argon and oxygen (Ar/O₂) were separately introduced thereinto as a reactive gas, followed by plasma treatment by 12 patterns. The color change of the color-changing layer of each indicator was then evaluated.

Table 2 shows the plasma treatment conditions.

TABLE 2

| | Ar Plasma | CF₄ Plasma | O₂ Plasma | Ar/O₂ Plasma |
|---|---|---|---|---|
| Gas type | Ar | CF₄ | O₂ | Ar/O₂ |
| Flow rate (sccm) | 50 | 30 | 100 | Ar: 25, O₂:50 |
| Pressure (Pa) | 5 | 2 | 10 | 7.5 |
| Electrical power (W) | 800 | 500 | 500 | 600 |
| Time (min) | 10 | 3 | 10 | 10 |
| Substrate cooling | Yes | Yes | Yes | Yes |

FIG. 2 shows the relationship between the mean particle size and color difference (ΔE) of Bi₂O₃ fine particles. As is clear from the results shown in FIG. 2, a smaller mean particle size resulted in a greater color change (sensitivity) by plasma treatment and a greater ΔE.

### Test Example 2

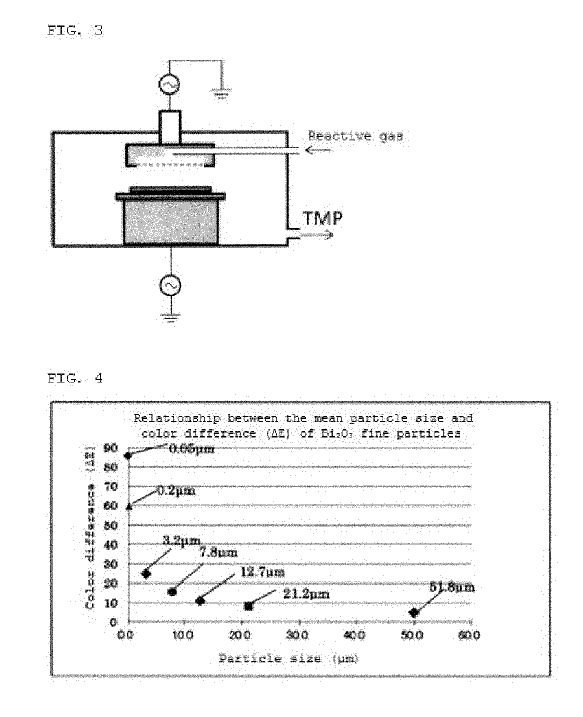

FIG. 3 is a schematic cross-sectional view of a CCP-type (parallel plate-type: capacitively coupled plasma) plasma etching apparatus.

The apparatus is provided with parallel-plate electrodes inside a vacuum vessel, and the upper electrode has a shower structure, by which a reactive gas is supplied to the surface of the object to be treated in a shower-like manner.

When etching is actually performed, the vacuum vessel is degassed, and then a reactive gas is introduced from the shower part of the upper electrode. High-frequency power supplied from the upper electrode generates plasma in the space of the parallel-plate electrodes, and the generated excited species cause a chemical reaction, which etches the surface of the object to be treated.

In Test Example 2, the indicators prepared using samples 1 to 7 were placed in this apparatus, argon gas (Ar) as a reactive gas was introduced thereinto, and plasma treatment was performed. The color change of the color-changing layer of each indicator was then evaluated.

Table 3 shows the plasma treatment conditions.

TABLE 3

| | Ar Plasma |
|---|---|
| Gas type | Ar |
| Flow rate (sccm) | 10 |
| Pressure (Pa) | 10 |
| Electrical power (W) | 50 |
| Time (min) | 10 |
| Substrate cooling | Water cooling |

FIG. 4 shows the relationship between the mean particle size and color difference (ΔE) of Bi₂O₃ fine particles. As is clear from the results shown in FIG. 4, a smaller mean particle size resulted in a greater color change (sensitivity) by plasma treatment and a greater ΔE.

1.-10. (canceled)

11. A plasma treatment detection indicator comprising a color-changing layer that changes color by plasma treatment,
the color-changing layer comprising metal oxide fine particles containing at least one element selected from the group consisting of Mo, W, Sn, V, Ce, Te, and Bi, the metal oxide fine particles having a mean particle size of 50 μm or less.

12. The plasma treatment detection indicator according to claim 11, wherein the metal oxide fine particles are at least one member selected from the group consisting of molybdenum(IV) oxide fine particles, molybdenum(VI) oxide fine particles, tungsten(VI) oxide fine particles, tin(IV) oxide fine particles, vanadium(II) oxide fine particles, vanadium(III) oxide fine particles, vanadium(IV) oxide fine particles, vanadium(V) oxide fine particles, cerium(IV) oxide fine particles, tellurium (IV) oxide fine particles, bismuth(III) oxide fine particles, bismuth(III) carbonate oxide fine particles, and vanadium(IV) oxide sulfate fine particles.

13. The plasma treatment detection indicator according to claim 11, wherein the metal oxide fine particles are at least one member selected from the group consisting of molybdenum(VI) oxide fine particles, tungsten(VI) oxide fine particles, vanadium(III) oxide fine particles, vanadium(V) oxide fine particles, and bismuth(III) oxide fine particles.

14. The plasma treatment detection indicator according to claim 12, wherein the metal oxide fine particles are at least one member selected from the group consisting of molybdenum(VI) oxide fine particles, tungsten(VI) oxide fine particles, vanadium(III) oxide fine particles, vanadium(V) oxide fine particles, and bismuth(III) oxide fine particles.

15. The plasma treatment detection indicator according to claim 11, comprising a base material that supports the color-changing layer.

16. The plasma treatment detection indicator according to claim 11, for use in an electronic device production equipment.

17. The plasma treatment detection indicator according to claim 16, which has a shape that is identical to the shape of an electronic device substrate for use in the electronic device production equipment.

18. The plasma treatment detection indicator according to claim 16, wherein the electronic device production equipment performs at least one plasma treatment selected from the group consisting of a film-forming step, an etching step, an ashing step, an impurity-adding step, and a washing step.

19. The plasma treatment detection indicator according to claim 17, wherein the electronic device production equipment performs at least one plasma treatment selected from the group consisting of a film-forming step, an etching step, an ashing step, an impurity-adding step, and a washing step.

20. The plasma treatment detection indicator according to claim 11, comprising a non-color-changing layer that does not change color by plasma treatment.

21. The plasma treatment detection indicator according to claim 20, wherein the non-color-changing layer contains at least one member selected from the group consisting of titanium(IV) oxide, zirconium(IV) oxide, yttrium(III) oxide, barium sulfate, magnesium oxide, silicon dioxide, alumina, aluminum, silver, yttrium, zirconium, titanium, and platinum.

22. The plasma treatment detection indicator according to claim 20, wherein the non-color-changing layer and the color-changing layer are formed on the base material in sequence,
the non-color-changing layer is formed adjacent to the principal surface of the base material, and
the color-changing layer is formed adjacent to the principal surface of the non-color-changing layer.

23. The plasma treatment detection indicator according to claim 21, wherein the non-color-changing layer and the color-changing layer are formed on the base material in sequence,
the non-color-changing layer is formed adjacent to the principal surface of the base material, and
the color-changing layer is formed adjacent to the principal surface of the non-color-changing layer.
